(19) United States
(12) Patent Application Publication
(10) Pub. No.: US 2024/0425978 A1
(43) Pub. Date: Dec. 26, 2024

(54) MODERATE TEMPERATURE CVD ALPHA ALUMINA COATING

(71) Applicants: WALTER AG, Tubingen (DE); FRAUNHOFER GESELLSCHAFT ZUR Förderung der angewandten Forschung e.V., Munich (DE)

(72) Inventors: Mandy Höhn, Munich (DE); Dirk STIENS, Tubingen (DE); Aleksandra GARDECKA, Tubingen (DE); Wiebke JANSSEN, Tubingen (DE); Thorsten MANNS, Tubingen (DE)

(21) Appl. No.: 18/708,220

(22) PCT Filed: Nov. 15, 2022
(86) PCT No.: PCT/EP2022/081899

§ 371 Date: May 8, 2024

(30) Foreign Application Priority Data
Nov. 16, 2021 (EP) 21208554.2

(51) Int. Cl. C23C 16/40; C23C 16/02; C23C 16/32; C23C 16/34; C23C 16/455; C23C 16/52; C23C 28/04

(52) U.S. Cl. CPC C23C 16/403; C23C 16/0272; C23C 16/32; C23C 16/34; C23C 16/45557; C23C 16/52; C23C 28/044

(57) ABSTRACT

A process for manufacturing a coated cutting tool for chip-forming metal machining having a substrate of cemented carbide, cermet or cubic boron nitride based ceramic material and a single-layered or multi-layered wear resistant hard coating is provided. Layers of the hard coating have at least one alpha phase Al₂O₃ coating layer deposited by chemical vapour deposition (CVD) at an average thickness from 1 μm to 20 μm. The deposition of the alpha phase Al₂O₃ coating layer occurs at a temperature in the range from 600 to 900° C., using a process gas composition, as introduced into the CVD reactor, including AICI₃, H₂O, H₂ and optionally HCl and/or a sulfur source, selected from H₂S, SF₆, SO₂ and SO₃. In the process gas composition, the volume ratio of H₂O/AlCl₃ is from 0.5 to 2.5, and the volume ratio of H₂/AlCl₃ is from 200 to 3000.

### FIELD OF THE INVENTION

The present invention relates to a surface-coated cutting tool consisting of a substrate body and a hard coating deposited on the substrate by a CVD process, the hard coating comprising at least one dense and hard Al₂O₃ layer of pure or mainly pure alpha phase (α-phase) deposited by a “moderate temperature” CVD (MT-CVD) process within the range from about 600-900° C. The invention further relates to a process for the deposition of such a α-Al₂O₃ layer at moderate temperature by CVD.

The coating of the cutting tool of the present invention has excellent wear resistance and peeling resistance in continuous and intermittent high-speed metal cutting.

### BACKGROUND OF THE INVENTION

Cutting tools of various substrate body materials, such as cemented carbide, cermet, cubic boron nitride, etc., coated with various types of hard layers, such as TIC, TIN, TiCN, TiAlN and Al₂O₃ have been commercially available for decades. Such tool coatings are generally built up by several hard layers in a multi-layer structure. The sequence and the thickness of the individual layers are carefully chosen to suit different cutting applications and workpiece materials.

Tool coatings are most frequently deposited by Chemical Vapour Deposition (CVD) or Physical Vapour Deposition (PVD) techniques. Both CVD and PVD have advantages and disadvantages over each other, and they result in different microstructural, physical and mechanical coating properties, thus, both techniques provide valuable coatings. One essential difference between the techniques is based on the different deposition temperatures. PVD deposition is carried out at temperatures in the order of about 450-700° C. and is performed under ion bombardment leading to high compressive stresses in the coating and no cooling cracks. In contrast, CVD for the deposition of hard tool coatings is carried out at higher temperatures in the order of about 880-1100° C. Due to this high deposition temperature and mismatch in thermal expansion coefficients between the deposited coating materials and the substrate material, such as cemented carbide, CVD produces coatings with cooling cracks and tensile stresses. Because of these process differences CVD coated tools are more brittle and thereby possess inferior toughness behaviour compared to PVD coated tools.

However, the CVD technique is suitable and advantageous to deposit many excellent hard and wear resistant coating materials, such as Al₂O₃, ZrO₂, and various Ti and TiAl compounds, e.g. Ti(C,N), TiAl(C,N) etc. The microstructure and thereby the properties of these coatings can be altered by varying the deposition conditions. If the standard CVD deposition temperature could be decreased significantly, an increased toughness and improvement of other properties of the coatings would be expected.

A noticeable improvement in the toughness behaviour and performance of CVD coated tools came about with the application of the MT-CVD (“moderate temperature” CVD) technique in the tool industry. The MT-CVD technique works at deposition temperatures in the range of about 700-900° C. and is well established for the deposition of Ti(C,N)-layers from a gas mixture containing TiCl₄, CH₃CN and H₂.

Modern tool coatings should include at least one polycrystalline layer of Al₂O₃ in order to achieve high wear resistance, hardness etc. It is well known that Al₂O₃ crystallises in several different phases: α, κ, γ, δ, θ etc. The most common CVD deposition temperature for Al₂O₃ is in the range 980-1050° C. At these temperatures both metastable κ-Al₂O₃ and stable α-Al₂O₃ or mixtures thereof can be produced. Occasionally, also the θ-phase can be present in smaller amounts.

However, the high temperature commonly used for the deposition of Al₂O₃ may lead to embrittlement of the substrate and/or decomposition of thermodynamically metastable materials in the layers underneath the Al₂O₃ deposition, such as TiAlN etc. Therefore, to avoid the disadvantages going along with high temperature CVD depositions to the deposited Al₂O₃ layer itself, but also to the layers and the substrate underneath, it would be desirable if also high quality Al₂O₃ layers, especially single phase stable α-Al₂O₃ layers, could be deposited by a CVD process at lower temperatures in the range similar to that of the MT-CVD process.

Various attempts have been made to deposit Al₂O₃ by CVD at low temperature. However, at present, no suitable and economically feasible process is known for the CVD deposition of single phase stable α-Al₂O₃ layers at low temperatures on cutting tools.

EP 1 947 213 B1 describes a process to deposit α-Al₂O₃ at a temperature in the range from about 625-800° C. The Al₂O₃ deposition requires pre-deposition of an underlying oxygen rich TiCNO layer, which further has to be treated with an oxygen containing gas mixture before the subsequent Al₂O₃ deposition can be carried out. The Al₂O₃ deposition process requires high concentration of CO₂ and a sulfur dopant, such as H₂S. If the oxygen treatment step is excluded, then mainly amorphous or metastable phases of Al₂O₃ are formed.

The deposition of the underlying TiCNO layer can either be deposited at 450-600° C. using PVD technique or at 1000-1050° C. using CVD technique. If CVD is used, the required oxygen treatment step to the TICNO layer, prior to the start of the Al₂O₃ deposition, is also carried out at high temperature around 1000° C. or above. Thus, either two different deposition techniques have to be applied, PVD and CVD, going along with the need to provide double equipment and to transfer the samples between completely different coating devices. And, if one or more additional CVD layers are deposited underneath the TICNO layer, as it is described for some embodiments of EP 1 947 213, even more than only one transfer of the samples from CVD to PVD and back to CVD equipment are required. Or, high temperature CVD has to be applied to deposit the TICNO layer and to carry out the oxidation step, going along with all the disadvantages of high temperature treatment to the substrate and/or any further underlying layers of the multi-layer coating.

The subsequent Al₂O₃ deposition process is carried out by CVD at a process pressure of 40-300 mbar and a temperature of 625-800° C., and using a reaction gas composition of AlCl₃, CO₂, H₂, H₂S and preferably HCl, whereby the CO₂ concentration is very high in the order of 16-40 vol.-% of the reaction gas composition.

EP 3 505 282 A1 describes a cutting tool with a multi-layer hard CVD coating comprising a lower layer of a complex nitride or complex carbonitride of Ti and Al, (Ti, Al) (C,N), an adhesion layer, and an upper layer of α-Al₂O₃. The authors have found that, in a case where an α-Al₂O₃ layer is deposited directly on a (Ti,Al) (C,N) lower layer under typical CVD conditions at about 1000° C., phase separation of AlN occurs in the (Ti,Al) (C,N) layer, and a sufficient hardness for the (Ti,Al) (C,N) layer is not obtained. On the other hand, in a case where an α-Al₂O₃ layer is formed on the surface of a (Ti,Al) (C,N) layer at a temperature range as low as 700° C. to 900° C., amorphous Al₂O₃ is formed on the outermost surface of the (Ti,Al) (C,N) layer, and the adhesion strength between the (Ti,Al) (C,N) layer and the α-Al₂O₃ layer is not sufficient.

The authors have found that adhesion strength between the (Ti,Al) (C,N) layer and the α-Al₂O₃ layer can be improved by providing an adhesion layer of TiCN with an increased oxygen content in the vicinity of the surface being in contact with the α-Al₂O₃ upper layer, which can then be formed under relatively low temperature conditions in the range from 800-900° C. at a process pressure of 5-15 kPa, and using a reaction gas composition of AlCl₃, CO₂, H₂ and HCl in the nucleation step and an additional amount of H₂S during layer growth.

Connelly, R. et al., “Development of moderate temperature CVD Al₂O₃ coating”, International Journal of Refractory Metals & Hard Materials 23 (2005) 317-321, describe further attempts to reduce the temperature for the CVD deposition of Al₂O₃ to a moderate temperature range of about 700-900° C. to allow for the MT-CVD deposition of intermediate Ti(C,N) coatings and Al₂O₃ within the same temperature range for economic reasons.

The Al₂O₃ deposition from AlCl₃ requires H₂O as the oxygen donor, which in the standard prior art CVD process is generated in situ in the water-gas shift reaction from H₂+CO₂-->H₂O+CO. Connelly, R. et al., have investigated further sources of water for this reaction, such as NO+H₂, NO2+H₂, CHOOH, and H₂O₂, and the thermodynamics and kinetics of these systems at various temperatures from 700-950° C. The thermodynamic calculations have identified NO+H₂ and HCOOH systems as the most potential sources of oxygen donors to form alumina in the moderate temperature range of 700-950° C. The authors describe that dense, uniform and adherent alumina coatings can be deposited on TiC and TiCN coated cemented carbide cutting tools at 870° C. using the AlCl₃+CHOOH+H₂ system. XRD analyses showed that the deposited Al₂O₃ coatings contained alpha and kappa phases.

Funk, R. et al., “Coating of Cemented Carbide Cutting Tools with Alumina by Chemical Vapor Deposition”, J, Electrochem. Soc., Vol. 123, No. 2, pp. 285-289, compare the standard prior art process providing the H₂O, in addition to AlCl₃, by the water-gas shift reaction from H₂+CO₂ (“H₂—CO₂ process”) and the process, wherein H₂O is directly introduced (“H₂O process”) over broad temperature ranges and on uncoated and TIC, TiN or Cr pre-coated cemented carbide substrates. The authors could show that in the H₂O process at 5 Torr the alumina deposition rate decreased within increasing deposition temperature (from 600-1000° C.), whereas in the H₂—CO₂ process at 50 Torr the deposition rate increased within increasing deposition temperature (from 750-1100° C.). It was found that adherence of the TiC and TIN pre-coated substrates was better than on uncoated cemented carbide, and on Cr pre-coated substrates non-adherent deposits were formed. For the standard H₂—CO₂ process the coatings contained α-Al₂O₃ over the temperature range from 850-1100° C., whereas nothing is said about modification, quality, phase purity or any microstructural, physical or mechanical properties of the deposition produced by the H₂O process.

Mäntylä et al., Proc. 5th EuroCVD, Jun. 17-20, 1985, have also investigated the deposition behaviour of Al₂O₃ in a temperature range from 250-1000° C. directly introducing H₂O gas in the reaction with AlCl₃ (“H₂O process”) to increase the deposition rate in order to use the CVD layer to densify the surface of porous plasma sprayed Al₂O₃. However, the coatings deposited at 250-500° C. were mainly amorphous, the amount of amorphous phase decreased with increasing temperature, and only at temperatures higher than 750-800° C. crystalline Al₂O₃ was obtained at all, whereby only at 1000° C. stable α-Al₂O₃ was obtained.

Similar studies were made by Schachner et al., Ber. Dt. Keram. Ges. 49/3 (1972), 76-80, who directly introduced H₂O to hydrolyse AlCl₃ in the CVD reaction carried out in a temperature range from 200-500° C. However, as confirmed by the later studies of Mäntylä et al., only amorphous Al₂O₃ was obtained.

### OBJECT OF THE INVENTION

The object underlying the present invention was to provide an improved and economic process for the low temperature CVD deposition of an alpha phase Al₂O₃ coating layer of good crystallinity, high hardness and density.

### DESCRIPTION OF THE INVENTION

The present invention provides a new process for manufacturing a coated cutting tool for chip-forming metal machining consisting of a substrate of cemented carbide, cermet or cubic boron nitride based or other ceramic material and a single-layered or multi-layered wear resistant hard coating, the layers of the hard coating comprise at least one alpha (a) phase Al₂O₃ coating layer being deposited by chemical vapour deposition (CVD) at an average thickness in the range from 1 μm to 20 μm, wherein the deposition of the alpha phase Al₂O₃ coating layer is carried out
at a temperature in the temperature range from 600 to 900° C.,
using a process gas composition, as introduced into the CVD reactor, comprising or consisting of AlCl₃, H₂O, H₂ and optionally HCl and/or a sulfur source, selected from H₂S, SF₆, SO₂ and SO₃,
   wherein in the process gas composition, as introduced into the CVD reactor,
the volume ratio of H₂O/AlCl₃ is in the range from 0.5 to 2.5, and
the volume ratio of H₂/AlCl₃ is in the range from 200 to 3000.

The process of the present invention overcomes several deficiencies of the prior art and it allows for the deposition and controlled growth of a Al₂O₃ coating layer of pure or almost pure alpha phase of good crystallinity, high hardness and density at comparably low temperature.

The standard H₂—CO₂ process for the deposition of α-Al₂O₃ requires high temperature in the order of 1000° C. and above, which may lead to embrittlement of the substrate and decomposition of thermodynamically metastable materials in the layers underneath the Al₂O₃ deposition. The process of the present invention overcomes this deficiency of high temperature deposition. The also known H₂O process may deposit Al₂O₃ at temperatures as low as 250° C., however, none of the prior art H₂O processes was suitable to deposit pure or almost pure alpha phase Al₂O₃ of the quality obtained by the process of the present invention. In the prior art H₂O processes either no alpha phase Al₂O₃ at all was obtained or only a certain amount of α-Al₂O₃ in admixture with significant amounts of other disadvantageous phases, such as gamma or theta phase, and/or amorphous Al₂O₃. The process of the present invention allows for the deposition of pure or almost pure high quality α-Al₂O₃ without the deteriorating effect of a too high deposition temperature on the material underneath.

In the process of the present invention the deposition of the alpha phase Al₂O₃ coating layer is carried out at a temperature in the temperature range from 600 to 900° C. If the temperature is less than 600° C., no alpha phase Al₂O₃ or alpha phase in admixture with significant amounts of other disadvantageous phases was observed, and layers of poor crystallinity and bad adhesion were obtained. If the temperature is higher than 900° C., the deteriorating effect on instable or metastable material underneath is too high. In an embodiment of the invention the deposition of the alpha phase Al₂O₃ coating layer is carried out at a temperature in the temperature range from 600 to 850° C. The temperature of 850° C. or less further reduces the risk of phase transformation of underlying material and the risk of depositing porous Al₂O₃ layers due to gas phase reactions.

It has surprisingly been found that this is achieved in a H₂O process at comparably low deposition temperature, if the ratio of H₂O/AlCl₃ is in the range from 0.5 to 2.5, and at the same time, the ratio of H₂/AlCl₃ is in the range from 200 to 3000 in the process gas composition, as introduced into the CVD reactor.

If the ratio of H₂O/AlCl₃ is too low, lower than 0.5, no pure or almost pure alpha phase is obtained and/or the deposition rate would be extremely low that the process would no longer be economically feasible.

If the ratio of H₂O/AlCl₃ is higher than 2.5, no alpha phase, but only gamma phase Al₂O₃ is deposited, even if the ratio of H₂/AlCl₃ is in the range from 200 to 3000.

If the ratio of H₂/AlCl₃ is too low, lower than 200, no alpha phase Al₂O₃ is deposited, but only gamma phase or mixtures of gamma and theta phase, and in some cases a powdery layer is obtained with bad or no adherence, even if the ratio of H₂O/AlCl₃ is in the range from 0.5 to 2.5.

If the ratio of H₂/AlCl₃ is too high, higher than 3000, no pure or almost pure alpha phase is obtained and/or the process would no longer be economically feasible either due to an extremely low deposition rate or due to the need to technically handle extremely high volume flows of H₂.

Thus, both reaction gas conditions must be met at the same time, i.e. the ratio of H₂O/AlCl₃ from 0.5 to 2.5 and the ratio of H₂/AlCl₃ from 200 to 3000, to allow for the deposition and controlled growth of a α-Al₂O₃ coating layer of good crystallinity, high hardness and density at the comparably low deposition temperature of the present invention.

The process of the present invention allows for the deposition of the α-Al₂O₃ coating layer even on top of substrates and/or further layers underneath, which are instable or less stable or are susceptible to embrittlement or any other disadvantageous changes at higher temperatures. At the same time, the process of the present invention provides a sufficiently high deposition rate to make the production of several micrometre thick wear resistant layers economically feasible.

The process of the present invention is suitable for commonly used industrial CVD equipment designs, and the deposition of the α-Al₂O₃ coating layer can be carried out in the same deposition run as further coating layers of a multi-layer coating structure, which is cost and time effective in the mass production of coated cutting tools. No separate manufacturing steps, such as intermediate PVD depositions, are required.

The α-Al₂O₃ coating layers produced by the process of the present invention provide good wear resistance and mechanical properties, as they exhibit high crystallinity, high hardness and density.

In comparison to conventional processes for the deposition of α-Al₂O₃ coating layers at high temperature, the process of the present invention runs at significantly lower temperatures leading to lower energy consumption and potentially lower production costs.

In a preferred embodiment of the present invention the deposition of the alpha phase Al₂O₃ coating layer is carried out at a total pressure in the range from 3 to 50 mbar, or from 3 to 30 mbar, or from 3 to 20 mbar, or from 3 to 15 mbar.

If the total pressure is too low, the deposition rate may decrease. Furthermore, the generation of process vacuum while evacuating corrosive precursors and by-products may require exceedingly high technical and financial resources.

If the total pressure is too high, no pure or almost pure alpha phase is obtained. Furthermore, the higher reactive gas partial pressures may lead to undesired gas phase reactions and may not result in compact layers.

In another preferred embodiment of the present invention in the deposition of the alpha phase Al₂O₃ coating layer in the process gas composition, as introduced into the CVD reactor, the ratio of H₂O/AlCl₃ is in the range from 0.7 to 2.0, or in the range from 0.8 to 1.5. It was observed that ratios of H₂O/AlCl₃ in this range may improve the homogeneity of coating thickness distribution within the reactor.

In another preferred embodiment of the present invention in the deposition of the alpha phase Al₂O₃ coating layer in the process gas composition, as introduced into the CVD reactor, the ratio of H₂/AlCl₃ is >500, or >800, or >1200, or >1400, or >1600.

It was observed that a higher ratio of H₂/AlCl₃ may further improve the purity of the alpha phase Al₂O₃ deposition and a more homogeneous coating thickness profile within the reactor.

In another preferred embodiment of the present invention in the deposition of the alpha phase Al₂O₃ coating layer the process gas composition, as introduced into the CVD reactor, consists of AlCl₃, H₂O and H₂, or the process gas composition additionally contains a sulfur source, preferably H₂S, in an amount of up to 2 vol.-% of the process gas.

In a preferred embodiment of the present invention the process gas composition, as introduced into the CVD reactor, contains no additional HCl. However, the invention includes embodiments, wherein in the deposition of the alpha phase Al₂O₃ coating layer the process gas composition, as introduced into the CVD reactor, additionally contains HCl in an amount of not more than 10 times the volume amount of AlCl₃ in the process gas.

In a preferred embodiment of the present invention the deposition process includes the deposition of further layers underneath the alpha phase Al₂O₃ coating layer, i.e. the deposition of a multi-layer structure. The further layers preferably include one or more Ti and/or Ti+Al compound layers being selected from carbides, nitrides, oxides, carbonitrides and oxicarbonitrides. The further layers, including the further Ti and/or Ti+Al compound layers, may be suitable to improve adhesion of the coating and/or promote a preferred crystallographic orientation or texture of the α-Al₂O₃ coating layer and/or of further layers and/or contribute and improve the wear resistance of the entire coating structure.

In one preferred example the layers deposited underneath the alpha phase Al₂O₃ coating layer include a layer sequence of a titanium nitride (TiN) lower layer, followed by one or more subsequent layers selected from titanium carbonitride (TiCN), titanium aluminium carbonitride (TiAlCN) and titanium aluminium nitride (TiAlN), optionally followed by a bonding layer immediately underneath the alpha phase Al₂O₃ coating layer according to the invention, which bonding layer preferably includes titanium carbonitride (TiCN) or titanium aluminium carbonitride (TiAlCN). In an embodiment of the invention, the bonding layer includes an oxidized state of the TiCN or TiAlCN near the transition region to or immediately underneath the alpha phase Al₂O₃ coating layer, which either depositing a TiCNO or TiAlCNO sub-layer or by carrying out an oxidation step to the TiCN or TiAlCN of the bonding layer prior to the deposition of the alpha phase Al₂O₃ coating layer. The provision of the oxidized state may further improve the adhesion of the alpha phase Al₂O₃ coating layer.

In an embodiment of the invention the deposition process includes an oxidation step prior to the deposition of the alpha phase Al₂O₃ coating layer. Preferably, the oxidation step is applied to a Ti and/or Ti+Al compound layer deposited underneath the Al₂O₃ coating layer. It was found that the application of an oxidation step may be suitable to improve the adhesion of the subsequently deposited alpha phase Al₂O₃ coating layer.

Preferably the oxidation step is carried out in the presence of H₂O as oxidizing agent for a time of about 2 to 20 min, preferably, about 3 to 15 min. In one embodiment the temperature of the oxidation step is about the same as or plus/minus 50° C. of the temperature applied for the deposition of the alpha phase Al₂O₃ coating layer.

The present invention also includes the surface-coated cutting tool for chip-forming metal machining consisting of a substrate of cemented carbide, cermet or cubic boron nitride based ceramic material and a single-layered or multi-layered wear resistant hard coating, wherein the layers of the hard coating comprising at least one alpha (a) phase Al₂O₃ coating layer being deposited by the chemical vapour deposition (CVD) process as defined herein.

The inventive cutting tool of the present invention distinguishes from cutting tools having at least one conventionally produced alpha (a) phase Al₂O₃ coating layer at high temperature in that the substrate and/or further layers underneath the Al₂O₃ coating layer have not undergone structural changes and deteriorations due to a high temperature deposition or treatment step. Therefore, the inventive cutting tool may, due to the inventive deposition process, exhibit improved mechanical properties and wear resistance. Furthermore, since the process of the present invention is carried out at significantly lower temperatures, the cutting tool of the present invention can be produced at lower costs and less consumption of resources than comparable cutting tools having at least one α-Al₂O₃ coating layer conventionally produced at high temperature.

In an embodiment of the surface-coated cutting tool of the invention the at least one alpha phase Al₂O₃ coating layer deposited by the inventive process has a Vickers hardness HV0.01 of >2000 HV, or >2300 HV.

In another embodiment of the invention the wear resistant hard coating of the surface-coated cutting tool further comprises one or more Ti and/or Ti+Al compound layers underneath the alpha phase Al₂O₃ coating layer, the Ti and/or Ti+Al compound layers being selected from carbides, nitrides, oxides, carbonitrides and oxicarbonitrides.

### Materials and Methods

### X-Ray Diffraction (XRD) Measurements

X-ray diffraction measurements were performed in a XRD3003 PTS diffractometer of GE Sensing and Inspection Technologies using CuKα-radiation. The X-ray tube was run in point focus at 40 kV and 40 mA. A parallel beam optic using a polycapillary collimating lens with a measuring aperture of fixed size was used on the primary side whereby the irradiated area of the sample was defined in such manner that a spillover of the X-ray beam over the coated face of the sample was avoided. On the secondary side a parallel plate collimator with a divergence of 0.4° and a 25 μm thick NiKβ filter was used. Depending on the layer thicknesses, diffraction measurements for identification of the Al₂O₃ phase were either performed by 20 scans at constant incidence angle of ω=1°, or by symmetrical 0-20 scans within the angle range of 15°≤20 $90° with increments of 0.04°.

### Microhardness Measurements

The microhardness was measured with the Vickers hardness test. For this purpose, a diamond pyramid (with interfacial angle of 136°, Vickers pyramid) was pressed into the layer with a defined test load. In accordance with DIN EN ISO 4516 a smooth calotte grind was used for the test. A smooth surface is necessary to minimize surface effects on measurement. The indenter is placed in the outer area of the coating to ensure that the indention depth is lower than 1/10 of the layer thickness. The diagonals of the indenter's remaining impression were measured optically. An MHT-10 (Anton Paar) installed on a light microscope was used to perform the indentation and measurements. The hardness was calculated by software using the average of the two diagonal lengths according to following equation (F is the test load and d is the average of diagonal lengths):

$$HV = 0.1891 * \frac{F}{{d}^{2}}$$

### Calotte Grinding

Calotte grinding was used to assess coating thickness and adhesion. The insert was placed on an inclined magnetic holder of the ball cratering set-up. A spherical calotte was ground in the coating and substrate material by a rotating 30 mm steel ball wetted with a drop of 3 μm water-based diamond suspension (Struers, DP-Lubricant Green) and driven by a driving shaft at >500 rpm. The grinding process was stopped when the calotte diameter in the substrate material reached approx. 600-1100 μm. The thickness measurements taking into account the geometry of the calottes were done by a dedicated software using light optical microscopy (LOM).

### “A” Adhesion

“A” adhesion defines the adhesion of the α-Al₂O₃ layer to the underlying layer. “A” adhesion was assessed by LOM observation on polished calotte ground surfaces and visually classified on a scale from 1.0 (=perfect adhesion) to 3.0 (=no adhesion). The criteria for “A” adhesion at the interfaces of layers/sublayers are as follows:
A=1: no or neglectable breakouts are observable at the interfaces, the interface line is intact.
A=2: minor breakouts can be observed at the interface, about 51-80% of the total interface line are without deterioration.
A=3: mayor breakouts or a continuous delamination are observable at the interface, 50-100% of the interface line in the calotte are deteriorated.

### Cutting Tests (Milling)

Coated cutting tools were tested herein in a milling operation in 42CrMo4 steel having a tensile strength of 785 N/mm² using the following cutting data:
Cutting speed v_{c}: 180 m/min
Cutting feed, f: 0.2 mm/revolution
Depth of cut, aₚ: 3 mm
Width of cut, aₑ: 98 mm
Radial overhang, uₑ: 5 mm
No. of teeth: 1
Insert geometry: SPHW120408
(no cutting fluid)

### CVD Coatings

The CVD coatings of the examples given herein below were done on WC-Co-based cemented carbide cutting tool substrates. In the examples herein, two different types of CVD equipment were used, lab scale and industrial scale CVD equipment.

Volumes of gases fed into the reactor were controlled by mass flow control units calibrated to flows in mln/min (normal milliliter per minute), In/min (normal liter per minute) or sccm (standard cubic centimeter per minute) which according to the technical data given by the manufacturer (Bronkhorst) all refer to conditions of 0° C. and 1.013 bar (abs.). The volume of evaporated H₂O was controlled and converted into units of sccm as described below. AlCl₃ was generated in situ and evaporated using the technically and industrially common technique of chlorinating Al pellets with HCl gas at elevated temperatures. As usual in publications of thermal CVD of aluminum oxide, it is reasonably assumed that the chlorination reaction Al+3 HCl→AlCl₃+1.5 H₂ proceeds almost instantaneously and quantitatively, yielding only the monomer molecule of aluminum trichloride. Process gas compositions and volume ratios given herein take AlCl₃ and H₂ flows into account accordingly.

In the equipment and working examples described herein, the process gas mixture is introduced into the reactor by two separate gas inlets. AlCl₃, optionally additional HCl and/or sulfur containing gases and H₂ are fed in through one, H₂O and remainder of H₂ through another inlet. However, the present invention is not limited to specific setups of reactor design and gas feeding systems.

Equipment “A” is a lab-scale horizontal flow hot wall CVD reactor made of Inconel and having an inner diameter of 79 mm, a horizontal length of 800 mm and an inner volume of approximately 6 litres. The substrate temperature is controlled by a type K thermocouple. Reaction gases are introduced by separate gas inlets into the reaction zone. Equipment A was used for the preparation of CVD Al₂O₃ coatings of some of the inventive working examples and comparative examples described below. In the H₂O evaporator of this equipment, water was evaporated by bubbling H₂ carrier gas through liquid water at controlled pressure and temperature. The evaporated H₂O gas flow in sccm is calculated as follows:

$$v ( {H}_{2} O ) = \frac{p ( {H}_{2} O ) \times p}{{p}_{v} - p ( {H}_{2} O )} \times \frac{1}{R \times {T}_{0}} \times {V}_{m} \times V ( carrier gas )$$

wherein
v(H₂O)=gas flow of H₂O [ml/min]=gas flow of H₂O [sccm]
p(H₂O)=vapor pressure of H₂O [Torr]
p=normal pressure 760 [Torr]
pᵥ=pressure in evaporator [Torr]
R=universal molar gas constant 62.32 [I Torr mol⁻¹ K⁻¹]
T₀=reference temperature 273.15 [K]
Vₘ=molar volume 22.4 [I mol⁻¹]
V(carrier cas)=gas stream carrier gas introduced into the evaporator [ml/min]

Equipment “B” is an industrial sized radial flow CVD coating chamber with an inner reactor height of 1580 mm, an inner reactor diameter of 500 mm and an inner volume of approximately 300 litres. The reaction gas was fed into the reactor through a central gas inlet pipe and introduced into the reaction zone through openings distributed along the inlet pipe to provide an essentially radial gas flow over the substrate bodies. Equipment B was used for the preparation of CVD Al₂O₃ coatings of some of the inventive working examples and comparative examples described below. In the H₂O evaporator of this equipment, water was evaporated by spraying liquid water into a H₂ carrier gas stream at 100° C. under reduced pressure. The evaporated amount was controlled by a liquid mass flow controller calibrated to units of g/h from which the gas volume flow in sccm is calculated using the molar mass of H₂O and ideal gas volume at normal conditions 0° C. and 1.013 bar (abs.).

Volume ratios of the process gas composition as introduced into the reactor refer to the aforementioned gas flows in sccm.

If not otherwise indicated, in the examples herein, the reactor was filled with inserts up to about its full capacity, whereby sample inserts to be investigated were distributed at various different positions within the reactor, and the remaining sample positions within the reactor were filled with “scrap” inserts to simulate, as close as possible, full scale deposition conditions and volume usage within the respective reactor.

### Examples

### Depositions

For the inventive examples 11 to 116 and comparative examples C1 to C13 and CWG1 prepared herein, prior to the deposition of the Al₂O₃, the substrates were pre-coated with an about 0.6 μm thick TiN base layer and an about 5.4 μm thick TiCN layer using equipment B.

The process parameters and reaction gases for this deposition are indicated in table 1. The depositions of TiN and TiCN prior to the deposition of the Al₂O₃ were all carried out under the same process conditions and in the same equipment to make the examples comparable with respect to variations of the Al₂O₃ deposition conditions.

The process parameters and reaction gases for the deposition of Al₂O₃ layers in inventive examples 11 to 116 and comparative examples C1 to C13 and CWG1 are indicated in table 2. In some of the inventive and comparative examples (if indicated) an oxidation step was applied to the TiCN layer prior to the deposition of the Al₂O₃. Oxidations in equipment A were carried out at fixed H₂O flows of 12 sccm and in equipment B at fixed H₂O flows of 1333 sccm for a time and at a temperature as indicated in table 2 under “Ox-Time” and “Ox-Temp”, respectively.

In the comparative examples CWG1 and CWG2 the Al₂O₃ layer was deposited applying the the water-gas shift reaction from H₂+CO₂-->H₂O+CO. The layer sequences, process parameters and reaction gases introduced into the reactor for comparative example CWG1 are included in tables 1 and 2, whereas layer sequences, process parameters and reaction gases for comparative example CWG2 (prepared in equipment B) are indicated in table 3.

Table 4 shows the measured parameters of the Al₂O₃ layer of the inventive examples (11 to 116) and the comparative examples (C1 to C13, CWG1 and CWG2).

Table 5 shows cutting test results of inventive and comparative examples. For each example, four cutting edges were used in the milling test. The milling operation was interrupted after milling paths of 800 mm, 1600 mm, 3200 mm, 4800 mm and 5600 mm to evaluate the wear marks, which were flank wear width (Vb), maximum flank wear width (Vbₘₐₓ) and number of comb cracks (comb cracks). Each cutting edge was used until a maximum flank wear width Vbₘₐₓ of >0.30 mm was reached. Table 5 lists the wear data for the cutting edge of each variant, which showed the poorest wear resistance, i.e. with the shortest milling length to reach Vb,ₘₐₓ>0.30 mm, and had the largest wear width in case several edges exceeded 0.3 mm at the same interval of measurement.

TABLE 1
Process parameters and reaction gases during deposition of TiN base
layer and TiCN layer on samples I1 to I16 and C1 to C13 and CWG1

| | | Pressure | | | | | | | |
|---|---|---|---|---|---|---|---|---|---|
| | Temp | total | Time | Thickness | H₂ | N₂ | TiCl₄ | CH₃CN | HCl |
| Layer Type | [° C.] | [mbar] | [min] | [μm] | [sccm] | [sccm] | [sccm] | [sccm] | [sccm] |
| TiN (base layer) | 885 | 400 | 70 | 0.6 | 33333 | 33333 | 1670 | — | — |
| TiCN | 885 | 55 | 230 | 5.4 | 105000 | 10000 | 3070 | 833 | 10000 |

In the deposition of the TiCN layer on top of the TiN base layer each of the gas streams of TiCl₄ and CH₃CN started at a rate as for the TiN base layer (TiCl₄ = 1670 sccm; CH₃CN = 0 sccm) and were each continuously increased in a linear manner at 5000 sccm/min up to the values indicated in table 1.

TABLE 2
Process parameters and reaction gases during deposition of inventive and comparative Al₂O₃ layers

| | | | Pressure | | | | | | | | Ox | Ox | | | |
|---|---|---|---|---|---|---|---|---|---|---|---|---|---|---|---|
| | | Temp | total | Time | AlCl₃ | H₂O | H₂ | H₂S | CO₂ | HCl | Time | Temp | H₂O/ | H₂/ | H₂S/ |
| Sample | Equipment | [° C.] | [mbar] | [min] | [sccm] | [sccm] | [sccm] | [sccm] | [sccm] | [sccm] | [min] | [° C.] | AlCl₃ | AlCl₃ | AlCl₃ |
| I1 | A | 800 | 10 | 180 | 1.20 | 1.20 | 2200 | 0.5 | — | — | — | — | 1.000 | 1833 | 0.417 |
| I2 | A | 800 | 10 | 180 | 1.20 | 2.40 | 2200 | 1 | — | — | — | — | 2.000 | 1833 | 0.833 |
| I3 | A | 800 | 10 | 180 | 1.20 | 1.20 | 2200 | — | — | — | — | — | 1.000 | 1833 | — |
| I4 | A | 800 | 10 | 180 | 1.20 | 2.40 | 2200 | 1 | — | — | 5 | 800 | 2.000 | 1833 | 0.833 |
| I5 | A | 800 | 10 | 180 | 1.20 | 1.20 | 2200 | — | — | — | 5 | 800 | 1.000 | 1833 | — |
| I6 | A | 800 | 10 | 180 | 1.20 | 1.20 | 1800 | — | — | — | 5 | 800 | 1.000 | 1500 | — |
| I7 | A | 750 | 10 | 180 | 1.20 | 1.20 | 2200 | — | — | — | 5 | 750 | 1.000 | 1833 | — |
| I8 | A | 850 | 10 | 180 | 1.20 | 1.20 | 2200 | — | — | — | 5 | 850 | 1.000 | 1833 | — |
| I9 | A | 900 | 10 | 180 | 1.20 | 1.20 | 2200 | — | — | — | 5 | 900 | 1.000 | 1833 | — |
| I10 | A | 800 | 10 | 180 | 1.20 | 1.20 | 2200 | 10 | — | — | — | — | 1.000 | 1833 | 8.333 |
| I11 | B | 850 | 10 | 360 | 167 | 167 | 335333 | — | | | 10 | 850 | 1.000 | 1341 | — |
| I12 | B | 800 | 10 | 360 | 250 | 250 | 335333 | — | | | 10 | 800 | 1.000 | 1341 | — |
| I13 | B | 775 | 10 | 360 | 250 | 250 | 335333 | — | | | 10 | 775 | 1.000 | 1341 | — |
| I14 | B | 700 | 10 | 360 | 250 | 250 | 335333 | — | | | 10 | 700 | 1.000 | 1341 | — |
| I15 | B | 700 | 10 | 360 | 250 | 250 | 335333 | — | | | 10 | 800 | 1.000 | 1341 | — |
| I16 | B | 650 | 10 | 360 | 250 | 250 | 335333 | — | | | 10 | 650 | 1.000 | 1341 | — |
| C1 | A | 800 | 10 | 120 | 26.70 | 27.70 | 1800 | — | — | — | — | — | 1.037 | 67 | — |
| C2 | A | 800 | 10 | 120 | 6.70 | 6.90 | 850 | — | — | — | — | — | 1.030 | 127 | — |
| C3 | A | 800 | 10 | 120 | 26.70 | 27.70 | 1700 | 10 | — | — | — | — | 1.037 | 64 | 0.375 |
| C4 | A | 800 | 10 | 120 | 13.30 | 13.90 | 1700 | 10 | — | — | — | — | 1.045 | 128 | 0.752 |
| C5 | A | 800 | 10 | 180 | 1.20 | 3.60 | 2200 | 1 | — | — | — | — | 3.000 | 1833 | 0.833 |
| C6 | A | 800 | 10 | 180 | 1.20 | 3.60 | 2200 | 3.6 | — | — | — | — | 3.000 | 1833 | 3.000 |
| C7 | A | 800 | 10 | 120 | 26.70 | 1.20 | 2200 | — | — | — | 8 | 900 | 0.045 | 82 | — |
| C8 | A | 800 | 10 | 120 | 26.70 | 1.20 | 2200 | 3 | — | — | 8 | 900 | 0.045 | 82 | 0.112 |
| C9 | A | 800 | 10 | 180 | 26.70 | 1.20 | 2200 | 10 | — | — | — | — | 0.045 | 82 | 0.375 |
| C10 | A | 800 | 10 | 180 | 13.33 | 1.20 | 2200 | 10 | — | — | — | — | 0.090 | 165 | 0.750 |
| C11 | A | 800 | 10 | 180 | 6.67 | 1.20 | 2200 | 10 | — | — | — | — | 0.180 | 330 | 1.499 |
| C12 | A | 800 | 10 | 180 | 3.33 | 1.20 | 2200 | 10 | — | — | — | — | 0.360 | 661 | 3.003 |
| C13 | A | 800 | 10 | 180 | 13.33 | 1.20 | 2200 | 4.98 | — | — | — | — | 0.090 | 165 | 0.374 |
| CWG1 | A | 1000 | 65 | 180 | 80 | — | 5500 | 15 | 60 | 25 | 3 | 1000 | 0.000 | 68.8 | 0.188 |

TABLE 3
Process parameters and reaction gases for the deposition of sample CWG2

| | | Pressure | | | | | | | | | | | | |
|---|---|---|---|---|---|---|---|---|---|---|---|---|---|---|
| | Temp | total | Time | Thickness | H₂ | N₂ | TiCl₄ | CH₃CN | CH₄ | AlCl₃ | CO₂ | CO | H₂S | HCl |
| Layer Type | [° C.] | [mbar] | [min] | [μm] | [sccm] | [sccm] | [sccm] | [sccm] | [sccm] | [sccm] | [sccm] | [sccm] | [sccm] | [sccm] |
| TiN (base layer) | 900 | 160 | 51 | 0.5 | 52500 | 35000 | 880 | — | — | — | — | — | — | — |
| TiCN (step 1) | 900 | 75 | 90 | 9.0 | 50000 | 18000 | 1530 | 420 | — | — | — | — | — | — |
| TiCN (step 2) | 900 | 70 | 240 | | 68000 | 6000 | 1530 | 530 | — | — | — | — | — | — |
| BL-1 | 1000 | 400 | 20 | 1.5 | 40000 | 15000 | 1120 | — | 2000 | — | — | — | — | 1000 |
| BL-2 | 1000 | 70 | 4 | | 70000 | 10000 | 1250 | — | — | — | — | 1000 | — | 1000 |
| BL-3 | 1000 | 70 | 14 | | 70000 | 10000 | 1170 | 330 | — | — | — | 1000 | — | 1000 |
| BL-4 | 1000 | 70 | 6 | | 46500 | 20000 | 1930 | 430 | — | 360 | — | 2000 | — | — |
| BL-5 | 1000 | 70 | 14 | | 46500 | 20000 | 1930 | — | — | 300 | — | 3000 | — | — |
| BL-6 | 1000 | 45 | 10 | | 62500 | — | — | — | — | 300 | — | — | — | — |
| Oxidation | 1000 | 55 | 6 | — | 36000 | 20000 | — | — | — | — | 2000 | 5000 | — | — |
| α-Al₂O₃ (step 1) | 1000 | 55 | 30 | 6.0 | 66500 | — | — | — | — | 1000 | 2000 | 1000 | — | 1000 |
| α-Al₂O₃ (step 2) | 1000 | 75 | 320 | | 125000 | — | — | — | — | 1000 | 3600 | — | 380 | 1200 |

“BL” = Bonding Layer (multi-layer of 6 sub-layers)

TABLE 4
Measured parameters of Al₂O₃ layer

| | Layer | Depos. | | “A” | |
|---|---|---|---|---|---|
| | Thickness | Rate | Hardness | Adhesion | XRD |
| Sample | [μm] | [μm/h] | [HV0.01] | [1-3] | Comments |
| I1 | 2.7 | 0.90 | 2695 | 1.5 | α-Al₂O₃; little γ- Al₂O₃; small aluminium sulfide peaks |
| I2 | 4.6 | 1.53 | 2439 | 2 | α- Al₂O₃; no further Al₂O₃ phase; very small aluminium sulfide peaks |
| I3 | 2 | 0.67 | 2463 | 2 | α- Al₂O₃; no further Al₂O₃ phase detected |
| I4 | 1.5 | 0.50 | 2472 | 1.5 | α- Al₂O₃; no further Al₂O₃ phase detected |
| I5 | 1.1 | 0.38 | 2634 | 2 | α- Al₂O₃; no further Al₂O₃ phase detected |
| I6 | 3.9 | 1.29 | 2574 | 1.5 | α- Al₂O₃; no further Al₂O₃ phase detected |
| I7 | 1.1 | 0.36 | 2567 | 2 | α- Al₂O₃; no further Al₂O₃ phase detected |
| I8 | 1.4 | 0.46 | 2637 | 1.5 | α- Al₂O₃; no further Al₂O₃ phase detected |
| I9 | 1.2 | 0.40 | 2612 | 1.5 | α- Al₂O₃; no further Al₂O₃ phase detected |
| I10 | 2.8 | 0.93 | 2645 | 2 | α- Al₂O₃; no further Al₂O₃ phase detected |
| I11 | 4.9 | 0.82 | n.m. | 1 | α- Al₂O₃; no further Al₂O₃ phase detected |
| I12 | 7.9 | 1.32 | n.m. | 1 | α- Al₂O₃; no further Al₂O₃ phase detected |
| I13 | 7.7 | 1.28 | n.m. | 1.5 | α- Al₂O₃; no further Al₂O₃ phase detected |
| I14 | 7.8 | 1.30 | n.m. | 1 | α- Al₂O₃; no further Al₂O₃ phase detected |
| I15 | 9.1 | 1.52 | n.m. | 1.5 | α-Al₂O₃; little γ-Al₂O₃ |
| I16 | 8.5 | 1.42 | n.m. | 1.5 | α-Al₂O₃; little γ-Al₂O₃ |
| C1 | 3.8 | 1.90 | n.p.m. | 2.5 | γ-Al₂O₃; powdery layer |
| C2 | 0.6 | 0.30 | n.p.m. | 3 | little γ-Al₂O₃ |
| C3 | 14.8 | 7.40 | n.p.m. | 3 | γ-Al₂O₃; powdery layer |
| C4 | 13.7 | 6.85 | 1893 | 2 | γ-Al₂O₃ |
| C5 | 2.8 | 0.93 | 2130 | 3 | only γ-Al₂O₃ |
| C6 | 2.8 | 0.93 | 2097 | 2 | only γ-Al₂O₃ |
| C7 | 3.9 | 1.90 | 2402 | 1.5 | θ- Al₂O₃ + γ-Al₂O₃ mixture |
| C8 | 5.5 | 2.70 | 681 | 2 | α- Al₂O₃ + Al₂S₃ |
| C9 | 2.8 | 0.93 | 2510 | 2 | θ- Al₂O₃ + γ- Al₂O₃ mixture; strong aluminium sulfide peaks |
| C10 | 8.8 | 2.93 | 841 | 2.5 | θ- Al₂O₃ + γ- Al₂O₃ mixture; strong aluminium sulfide peaks |
| C11 | 5.6 | 1.87 | 948 | 2.5 | α- Al₂O₃ + γ- Al₂O₃ mixture; strong aluminium sulfide peaks |
| C12 | 1.6 | 0.53 | 2684 | 2.5 | θ- Al₂O₃ + α- Al₂O₃ mixture; small aluminium sulfide peaks |
| C13 | 3.0 | 1.00 | 2236 | 2.5 | θ- Al₂O₃ + γ- Al₂O₃ mixture; very strong aluminium sulfide peaks |
| CWG1 | 3.0 | 1.00 | 2542 | 1 | α- Al₂O₃; no further Al₂O₃ phase detected |
| CWG2 | 6.0 | 1.20 | n.m. | 1 | α- Al₂O₃; no further Al₂O₃ phase detected |

“n.m.” = not measured;
“n.p.m.” = not possible to measure

TABLE 5
Cutting test data

| | Turning Path | | | | | | | | | | | | | | |
|---|---|---|---|---|---|---|---|---|---|---|---|---|---|---|---|
| | 800 mm | | | 1600 mm | | | 3200 mm | | | 4800 mm | | | 5600 mm | | |
| | | | comb | | | comb | | | comb | | | comb | | | comb |
| Sample | Vb | Vbₘₐₓ | cracks | Vb | Vbₘₐₓ | cracks | Vb | Vbₘₐₓ | cracks | Vb | Vbₘₐₓ | cracks | Vb | Vbₘₐₓ | cracks |
| I1 | 0.08 | 0.15 | 0 | 0.12 | 0.16 | 1 | 0.16 | 0.27 | 4 | 0.21 | 0.66 | 6 | | | |
| I2 | 0.11 | 0.14 | 0 | 0.12 | 0.21 | 1 | 0.15 | 0.30 | 2 | 0.24 | 0.90 | 6 | | | |
| I3 | 0.06 | 0.10 | 1 | 0.08 | 0.15 | 1 | 0.12 | 0.24 | 1 | 0.15 | 0.30 | 1 | 0.15 | 0.32 | 1 |
| I4 | 0.09 | 0.15 | 0 | 0.11 | 0.24 | 1 | 0.12 | 0.27 | 2 | 0.13 | 0.34 | 2 | | | |
| I10 | 0.10 | 0.18 | 0 | 0.12 | 0.18 | 0 | 0.14 | 0.21 | 0 | 0.16 | 0.31 | 0 | | | |
| C10 | 0.05 | 0.15 | 0 | 0.10 | 0.94 | 0 | | | | | | | | | |
| C11 | 0.06 | 0.12 | 0 | 0.11 | 0.31 | 0 | | | | | | | | | |
| C12 | 0.07 | 0.14 | 1 | 0.13 | 0.85 | 1 | | | | | | | | | |

1. A process for manufacturing a coated cutting tool for chip-forming metal machining consisting of a substrate of cemented carbide, cermet or cubic boron nitride based ceramic material and a single-layered or multi-layered wear resistant hard coating, layers of the hard coating having at least one alpha (α) phase Al₂O₃ coating layer being deposited by chemical vapour deposition (CVD) at an average thickness in a range from 1 μm to 20 μm, wherein the deposition of the alpha phase Al₂O₃ coating layer is carried out:
at a temperature in the temperature range from 600 to 900° C.,
using a process gas composition, as introduced into a CVD reactor,
comprising or consisting of AlCl₃, H₂O, H₂ and optionally HCl and/or a sulfur source, selected from H₂S, SF₆, SO₂ and SO₃,
wherein in the process gas composition, as introduced into the CVD reactor,
a volume ratio of H₂O/AlCl₃ is in the range from 0.5 to 2.5, and
a volume ratio of H₂/AlCl₃ is in the range from 200 to 3000.

2. The process of claim 1, wherein the deposition of the alpha phase Al₂O₃ coating layer is carried out at a total pressure in the range from 3 to 50 mbar.

3. The process of claim 1, wherein in the deposition of the alpha phase Al₂O₃ coating layer in the process gas composition, as introduced into the CVD reactor, the ratio of H₂O/AlCl₃ is in the range from 0.7 to 2.0.

4. The process of claim 1, wherein in the deposition of the alpha phase Al₂O₃ coating layer in the process gas composition, as introduced into the CVD reactor, the ratio of H₂/AlCl₃ is >500.

5. The process of claim 1, wherein in the deposition of the alpha phase Al₂O₃ coating layer the process gas composition, as introduced into the CVD reactor, consists of AlCl₃, H₂O and H₂, or the process gas composition additionally contains a sulfur source of H₂S, in an amount of up to 2 vol.-% of the process gas.

6. The process of claim 1, wherein in the deposition of the alpha phase Al₂O₃ coating layer the process gas composition, as introduced into the CVD reactor, additionally contains HCl in an amount of not more than 10 times the volume amount of AlCl₃ in the process gas.

7. The process of claim 1, wherein the deposition process includes the deposition of one or more Ti compound layers underneath the alpha phase Al₂O₃ coating layer, the Ti and/or Ti+Al compound layers being selected from carbides, nitrides, oxides, carbonitrides and oxicarbonitrides.

8. The process of claim 1, wherein the deposition process includes an oxidation step prior to the deposition of the alpha phase Al₂O₃ coating layer.

9. The process of claim 1, wherein the deposition of the alpha phase Al₂O₃ coating layer is carried out at a temperature in the temperature range from 600 to 850° C.

10. A surface-coated cutting tool for chip-forming metal machining consisting of a substrate of cemented carbide, cermet or cubic boron nitride based ceramic material and a single-layered or multi-layered wear resistant hard coating, wherein the layers of the hard coating comprising at least one alpha (α) phase Al₂O₃ coating layer being deposited by the chemical vapour deposition (CVD) process according to claim 1.

11. The surface-coated cutting tool of claim 10, wherein the at least one alpha phase Al₂O₃ coating layer has a Vickers hardness HV0.01 of >2000 HV.

12. The surface-coated cutting tool of claim 10, wherein the wear resistant hard coating further comprises one or more Ti compound layers underneath the alpha phase Al₂O₃ coating layer, the Ti and/or Ti+Al compound layers being selected from carbides, nitrides, oxides, carbonitrides and oxicarbonitrides.
